(19) United States
(12) Patent Application Publication
(10) Pub. No.: US 2026/0050049 A1
(43) Pub. Date: Feb. 19, 2026

(54) THREE-AXIS MAGNETIC FIELD DETECTION DEVICE AND METHOD

(71) Applicant: DAEGU GYEONGBUK INSTITUTE OF SCIENCE AND TECHNOLOGY, Daegu (KR)

(72) Inventors: Cheol Gi KIM, Daegu (KR); Byeong Hwa LIM, Daegu (KR); Chang Yeop JEON, Busan (KR); Jin Woo KIM, Daegu (KR); Tae Hyeong JEON, Daegu (KR); Mi Jin KIM, Daegu (KR); Sung Hyeok LEE, Daegu (KR)

(73) Assignee: DAEGU GYEONGBUK INSTITUTE OF SCIENCE AND TECHNOLOGY, Daegu (KR)

(21) Appl. No.: 19/104,448

(22) PCT Filed: Oct. 11, 2023
(86) PCT No.: PCT/KR2023/015628

§ 371 Date: Feb. 18, 2025

(30) Foreign Application Priority Data
Oct. 14, 2022 (KR) 10-2022-0132108

(51) Int. Cl. G01R 33/02; G01R 33/07; G01R 33/09

(52) U.S. Cl. CPC G01R 33/0206; G01R 33/07; G01R 33/09

(57) ABSTRACT

A three-axis magnetic field detection device includes a magnetic field conversion unit for generating a stray field having a magnetic field direction according to a magnetic field direction of an outer magnetic field using magnetic particles, a magnetic field measurement unit for measuring a magnetic field direction with respect to an X-axis magnetic field and Y-axis magnetic field in relation to the outer magnetic field, and a magnetic field detection unit for detecting the X-axis magnetic field, the Y-axis magnetic field and the Z-axis magnetic field based on the stray field and the measured magnetic field direction.

### TECHNICAL FIELD

The present invention relates to a three-axis magnetic field detection device and method, and more particularly to a technology for generating a stray field having a magnetic field direction according to an outer magnetic field using a magnetic field conversion unit based on magnetic particles and detecting the three-axis magnetic field by detecting the magnetic field direction of the stray field through a magnetic sensor.

### BACKGROUND ART

Recently, various 3-axis magnetic sensors have been developed, and chip-type sensor modules have been developed and applied due to the development of miniaturization technology.

In particular, to detect various directions of magnetic fields of a magnetic sensor, a magnetic field converter capable of converting the direction of a magnetic field that cannot be detected into the direction of a magnetic field that can be detected is required.

In the past, the direction of a magnetic field was converted using a magnetic focusing device manufactured using a soft magnetic material.

This may cause inaccuracy in the measured magnetic field due to the occurrence of magnetic hysteresis in the magnetic material.

According to an existing technology, there are three strategies for manufacturing a 3-axis magnetic sensor.

First, there is a method of perpendicularly coupling three magnetic sensors that detect a specific axis of magnetic field.

The method has difficulty in securing reproducibility and accuracy for sensor manufacturing and an uneven sensor response.

Second, there is a method of converting a magnetic field to a measurable direction using a magnetic field converter when a magnetic field cannot be detected in a specific direction, such as a magnetoresistance sensor or a Hall sensor.

For this, a soft magnetic permalloy plate can be bound or manufactured using electroplating or an adhesive resin.

However, in the case of permalloy plates, magnetic hysteresis may occur, resulting in inaccurate magnetic field conversion rates. In addition, when using an adhesive resin, the position of a magnetic field converter may be inaccurate, which reduces the reproducibility of a manufacturing process.

Finally, there is a method of detecting a three-axis magnetic field by fabricating a sensor on a tilted wafer using a wet etching process.

In this case, there is a disadvantage in that sensor characteristics for an inclined plane, in addition to a sensor manufactured on a plane, should be designed.

### DISCLOSURE

### Technical Problem

Therefore, the present invention has been made in view of the above problems, and it is one object of the present invention to provide a three-axis magnetic field detection device and method for generating a stray field having a magnetic field direction according to an outer magnetic field using a magnetic field conversion unit based on magnetic particles and for detecting the magnetic field direction of the stray field through a magnetic sensor to detect a three-axis magnetic field.

It is another object of the present invention to detect a Z-axis magnetic field by the magnetic sensor by using a magnetic particle-based magnetic field converter that generates a stray field, together with magnetic sensor that measures and detects the X-axis and Y-axis magnetic fields.

It is still another object of the present invention to provide a three-axis magnetic field detection device and method that can be applied regardless of the type of sensor to detect a three-axis magnetic field as a magnetic particle-based magnetic field conversion unit included in the three-axis magnetic field detection device generates a stray field having a magnetization direction according to the direction of magnetic field.

It is still another object of the present invention to freely determine the positions of the magnetic sensor, which functions as a magnetic field measurement unit and a magnetic field detection unit, and the magnetic field converter, which functions as a magnetic field conversion unit, according to the manufacturer's intention using photolithography or inkjet and heat treatment processes, thereby improving reproducibility.

It is yet another object of the present invention to determine the positions of a magnetic sensor and a magnetic field converter in consideration of the characteristic that the output signal of a magnetic field detection unit is determined by the intensity of a stray field converted by the magnetic field conversion unit, thereby being capable of improving a magnetic field detection rate.

### Technical Solution

In accordance with an aspect of the present invention, the above and other objects can be accomplished by the provision of a three-axis magnetic field detection device, including: a magnetic field conversion unit for generating a stray field having a magnetic field direction according to a magnetic field direction of an outer magnetic field using magnetic particles: a magnetic field measurement unit for measuring magnetic field directions for an X-axis magnetic field, a Y-axis magnetic field and the stray field in relation to the outer magnetic field; and a magnetic field detection unit for detecting the X-axis magnetic field, the Y-axis magnetic field and the Z-axis magnetic field based on the measured magnetic field direction.

The magnetic field detection unit may detect the X-axis magnetic field when the magnetic field direction of the stray field is identical to the magnetic field direction of the X-axis magnetic field, and may detect the Z-axis magnetic field when the magnetic field direction of the stray field differs from the magnetic field direction of the X-axis magnetic field.

The magnetic field detection unit may detect the Y-axis magnetic field when the magnetic field direction of the stray field is identical to the magnetic field direction of the Y-axis magnetic field, and may detect the Z-axis magnetic field when the magnetic field direction of the stray field differs from the magnetic field direction of the Y-axis magnetic field.

When the outer magnetic field is either an X-axis magnetic field or a Y-axis magnetic field, the magnetic field conversion unit may generate a stray field having a magnetic field direction identical to that of either the X-axis magnetic field or the Y-axis magnetic field, and, when the outer magnetic field is a Z-axis magnetic field, the magnetic field conversion unit may generate a stray field having a magnetic field direction opposite to that of the Z-axis magnetic field.

The magnetic field measurement unit and the magnetic field detection unit may be included in each of a first magnetic sensor, a second magnetic sensor and a third magnetic sensor, the first magnetic sensor and the second magnetic sensor may be positioned under the magnetic field conversion unit, the third magnetic sensor may be positioned separately from the magnetic field conversion unit, the first magnetic sensor and the second magnetic sensor may detect the X-axis magnetic field and the Z-axis magnetic field, and the third magnetic sensor may detect the Y-axis magnetic field.

The magnetic field detection unit may detect the X-axis magnetic field by combining an output signal of the first magnetic sensor with an output signal of the second magnetic sensor and by dividing the output signal by the number of magnetic sensors that output the output signal, may detect the Z-axis magnetic field by excluding an output signal of the second magnetic sensor from the output signal of the first magnetic sensor and by dividing the output signal by the number of the magnetic sensors, and may detect an output signal of the third magnetic sensor as the Y-axis magnetic field.

The first magnetic sensor, the second magnetic sensor, the magnetic field conversion unit and the third magnetic sensor may be positioned on a first wafer substrate.

The first magnetic sensor, the second magnetic sensor and the magnetic field conversion unit may be positioned on the first wafer substrate, and the third magnetic sensor may be positioned on a second wafer substrate different from the first wafer substrate.

The magnetic field measurement unit and the magnetic field detection unit may be included in each of the first magnetic sensor, the second magnetic sensor, the third magnetic sensor and the fourth magnetic sensor, the first magnetic sensor, the second magnetic sensor, the third magnetic sensor and the fourth magnetic sensor may be positioned under the magnetic field conversion unit, the first magnetic sensor and the second magnetic sensor may detect the X-axis magnetic field and the Z-axis magnetic field, and the third magnetic sensor and the fourth magnetic sensor may detect the Y-axis magnetic field and the Z-axis magnetic field.

The magnetic field detection unit may detect the X-axis magnetic field by combining an output signal of the first magnetic sensor with an output signal of the second magnetic sensor and by dividing the output signal by the number of magnetic sensors that output the output signal, may detect the Z-axis magnetic field by excluding an output signal of the second magnetic sensor from the output signal of the first magnetic sensor and by dividing the output signal by the number of the magnetic sensors, may detect the Y-axis magnetic field by combining an output signal of the third magnetic sensor with an output signal of the fourth magnetic sensor and by dividing the output signal by the number of the magnetic sensors, and may detect the Z-axis magnetic field by excluding an output signal of the fourth magnetic sensor from the output signal of the third magnetic sensor and dividing the output signal by the number of the magnetic sensors.

In accordance with another aspect of the present invention, there is provided a three-axis magnetic field detection method, including: generating, by a magnetic field conversion unit, a stray field having a magnetic field direction according to a magnetic field direction of an outer magnetic field using magnetic particles: measuring, by a magnetic field measurement unit, magnetic field directions for an X-axis magnetic field, a Y-axis magnetic field and the stray field in relation to the outer magnetic field; and detecting, by a magnetic field detection unit, the X-axis magnetic field, the Y-axis magnetic field and the Z-axis magnetic field based on the measured magnetic field direction.

The detecting may include: detecting the X-axis magnetic field when the magnetic field direction of the stray field is identical to the magnetic field direction of the X-axis magnetic field; and detecting the Z-axis magnetic field when the magnetic field direction of the stray field differs from the magnetic field direction of the X-axis magnetic field.

The detecting may include: detecting the Y-axis magnetic field when the magnetic field direction of the stray field is identical to the magnetic field direction of the Y-axis magnetic field; and detecting the Z-axis magnetic field when the magnetic field direction of the stray field differs from the magnetic field direction of the Y-axis magnetic field.

### Advantageous Effects

The present invention can provide a three-axis magnetic field detection device and method for generating a stray field having a magnetic field direction according to an outer magnetic field using a magnetic field conversion unit based on magnetic particles and for detecting the magnetic field direction of the stray field through a magnetic sensor to detect a three-axis magnetic field.

The present invention can detect a Z-axis magnetic field by the magnetic sensor by using a magnetic particle-based magnetic field converter that generates a stray field, together with magnetic sensor that measures and detects the X-axis and Y-axis magnetic fields.

The present invention can provide a three-axis magnetic field detection device and method that can be applied regardless of the type of sensor to detect a three-axis magnetic field as a magnetic particle-based magnetic field conversion unit included in the three-axis magnetic field detection device generates a stray field having a magnetization direction according to the direction of magnetic field.

The present invention can freely determine the positions of the magnetic sensor, which functions as a magnetic field measurement unit and a magnetic field detection unit, and the magnetic field converter, which functions as a magnetic field conversion unit, according to the manufacturer's intention using photolithography or inkjet and heat treatment processes, thereby improving reproducibility.

The present invention can determine the positions of a magnetic sensor and a magnetic field converter in consideration of the characteristic that the output signal of a magnetic field detection unit is determined by the intensity of a stray field converted by the magnetic field conversion unit, thereby being capable of improving a magnetic field detection rate.

### DESCRIPTION OF DRAWINGS

FIG. 1 illustrates a three-axis magnetic field detection device according to an embodiment of the present invention.

FIG. 2 illustrates a first configuration according to the arrangement of a magnetic sensor, which includes a magnetic field measurement unit and a magnetic field detection unit, and a magnetic field conversion unit, in the three-axis magnetic field detection device according to an embodiment of the present invention.

FIGS. 3A and 3B illustrate a stray field generated in a magnetic field conversion unit of the three-axis magnetic field detection device according to an embodiment of the present invention.

FIG. 4 illustrates a second configuration according to the arrangement of a magnetic sensor, which includes a magnetic field measurement unit and a magnetic field detection unit, and a magnetic field conversion unit in the three-axis magnetic field detection device according to an embodiment of the present invention.

FIG. 5 illustrates a third configuration according to the arrangement of a magnetic sensor, which includes a magnetic field measurement unit and a magnetic field detection unit, and a magnetic field conversion unit in the three-axis magnetic field detection device according to an embodiment of the present invention.

FIG. 6 illustrates a three-axis magnetic field detection method according to an embodiment of the present invention.

### BEST MODE

Specific structural and functional descriptions of embodiments according to the concept of the present invention disclosed herein are merely illustrative for the purpose of explaining the embodiments according to the concept of the present invention. Furthermore, the embodiments according to the concept of the present invention can be implemented in various forms and the present invention is not limited to the embodiments described herein.

The embodiments according to the concept of the present invention may be implemented in various forms as various modifications may be made. The embodiments will be described in detail herein with reference to the drawings. However, it should be understood that the present invention is not limited to the embodiments according to the concept of the present invention, but includes changes, equivalents, or alternatives falling within the spirit and scope of the present invention.

The terms such as “first” and “second” are used herein merely to describe a variety of constituent elements, but the constituent elements are not limited by the terms. The terms are used only for the purpose of distinguishing one constituent element from another constituent element. For example, a first element may be termed a second element and a second element may be termed a first element without departing from the scope of rights according to the concept of the present invention.

It will be understood that when an element is referred to as being “on”, “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Other words used to describe the relationship between elements should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” in the specification should be construed as denoting that a certain characteristic, number, stage, operation, constituent element, component or a combination thereof exists and not as excluding the existence of or a possibility of an addition of one or more other characteristics, numbers, stages, operations, constituent elements, components or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present invention will now be described more fully with reference to the accompanying drawings, in which exemplary embodiments of the invention are shown. This invention may, however, be embodied in many different forms and should not be construed as limited to the exemplary embodiments set forth herein. Like reference numerals in the drawings denote like elements.

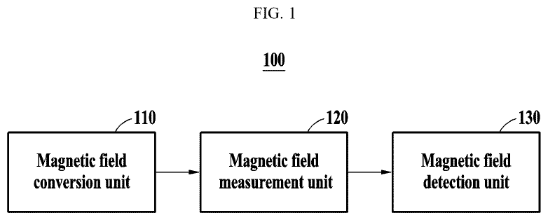

FIG. 1 illustrates a three-axis magnetic field detection device according to an embodiment of the present invention.

FIG. 1 illustrates the components of the three-axis magnetic field detection device according to an embodiment of the present invention.

Referring to FIG. 1, a three-axis magnetic field detection device 100 includes a magnetic field conversion unit 110, a magnetic field measurement unit 120 and a magnetic field detection unit 130.

The magnetic field conversion unit 110 may be referred to as a magnetic field converter and may be formed using superparamagnetic nanoparticles, which are magnetic particles, and an epoxy-type photoresist.

Accordingly, the magnetic field conversion unit 110 as a magnetic focusing device may determine different magnetic field conversion efficiencies for an outer magnetic field depending on a magnetization direction.

According to an embodiment of the present invention, since the magnetic field conversion unit 110 uses superparamagnetic nanoparticles, it does not have a magnetization direction and the magnitude converges to 0, when an outer magnetic field does not exist.

Accordingly, the magnetic field conversion unit 110 may always show the same magnetic field conversion efficiency for an outer magnetic field, unlike a soft magnetic material.

The magnetic field measurement unit 120 and the magnetic field detection unit 130 are included in a magnetic sensor.

That is, the magnetic sensor may perform the role of the magnetic field measurement unit 120 and the magnetic field detection unit 130.

For example, the three-axis magnetic field detection device 100 has poor reproducibility when manufacturing a magnetic sensor when using an adhesive resin. However, by using photolithography or inkjet and heat treatment processes, the positions of the magnetic sensor and the magnetic field conversion unit 110 may be freely determined to improve reproducibility.

According to an embodiment of the present invention, the magnetic field conversion unit 110 of the three-axis magnetic field detection device 100 may be formed by additionally coating an epoxy-based photoresist, mixed with magnetic particles, on the upper part of the magnetic sensor, and by using a photolithography process and a thermal curing process.

When a Z-axis magnetic field exists, a stray field that can be measured by the magnetic sensor in a plane direction is generated due to magnetic particles.

Since an output signal of the magnetic sensor is determined by the intensity of the stray field converted by the magnetic focusing device, the magnetic sensor should be placed at a location where the stray field is the strongest.

Depending on the type and size of the magnetic sensor, the magnetic field conversion unit 110 of various designs and sizes may be utilized, and its location may be determined.

According to an embodiment of the present invention, the magnetic field conversion unit 110 may generate a stray field having a magnetic field direction according to the magnetic field direction of an outer magnetic field using magnetic particles.

That is, the magnetic field conversion unit 110 may generate a stray field having a magnetic field direction opposite to a Z-axis magnetic field direction when a Z-axis magnetic field exists as an outer magnetic field.

According to an embodiment of the present invention, when the outer magnetic field is either an X-axis magnetic field or a Y-axis magnetic field, the magnetic field conversion unit 110 generates a stray field having a magnetic field direction identical to that of either the X-axis magnetic field or the Y-axis magnetic field, and, when the outer magnetic field is a Z-axis magnetic field, the magnetic field conversion unit 110 generates a stray field having a magnetic field direction opposite to that of the Z-axis magnetic field.

According to an embodiment of the present invention, the magnetic field measurement unit 120 may measure a magnetic field direction with respect to the X-axis magnetic field, the Y-axis magnetic field, and the stray field in relation to the outer magnetic field.

For example, the magnetic field detection unit 130 may detect the X-axis magnetic field, the Y-axis magnetic field and the Z-axis magnetic field based on the measured magnetic field direction.

According to an embodiment of the present invention, the magnetic field detection unit 130 may detect the X-axis magnetic field when the magnetic field direction of the stray field is the same as the magnetic field direction of the X-axis magnetic field, and may detect the Z-axis magnetic field when the magnetic field direction of the stray field differs from the magnetic field direction of the X-axis magnetic field.

For example, the magnetic field detection unit 130 may detect the Y-axis magnetic field when the magnetic field direction of the stray field is the same as the magnetic field direction of the Y-axis magnetic field, and may detect the Z-axis magnetic field when the magnetic field direction of the stray field differs from the magnetic field direction of the Y-axis magnetic field.

The magnetic field measurement unit 120 and the magnetic field detection unit 130 may be included in an X-axis magnetic sensor for measuring the X-axis magnetic field or a Y-axis magnetic sensor for measuring the Y-axis magnetic field.

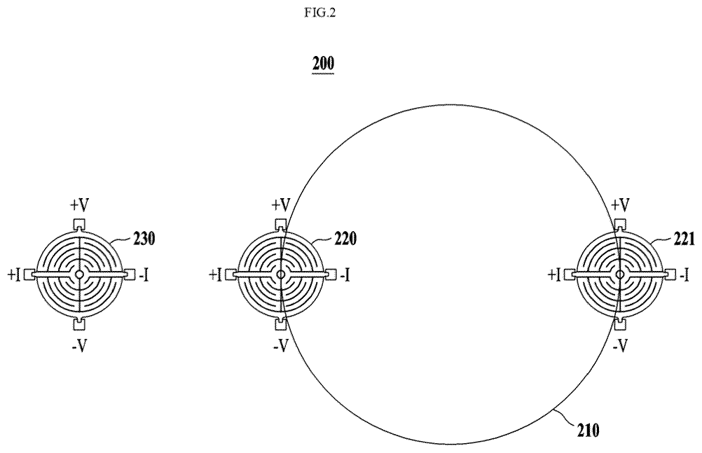

In the case of a magnetic field detection device designed according to a first configuration illustrated in FIG. 2, the magnetic field measurement unit and the magnetic field detection unit are included in a first magnetic sensor, a second magnetic sensor and a third magnetic sensor.

In addition, the first magnetic sensor and the second magnetic sensor may be positioned under the magnetic field conversion unit, and the third magnetic sensor may be positioned separately from the magnetic field conversion unit.

For example, the first magnetic sensor and the second magnetic sensor may detect the X-axis magnetic field and the Z-axis magnetic field, and the third magnetic sensor may detect the Y-axis magnetic field.

In addition, the first magnetic sensor, the second magnetic sensor, the magnetic field conversion unit and the third magnetic sensor may be positioned on one wafer substrate.

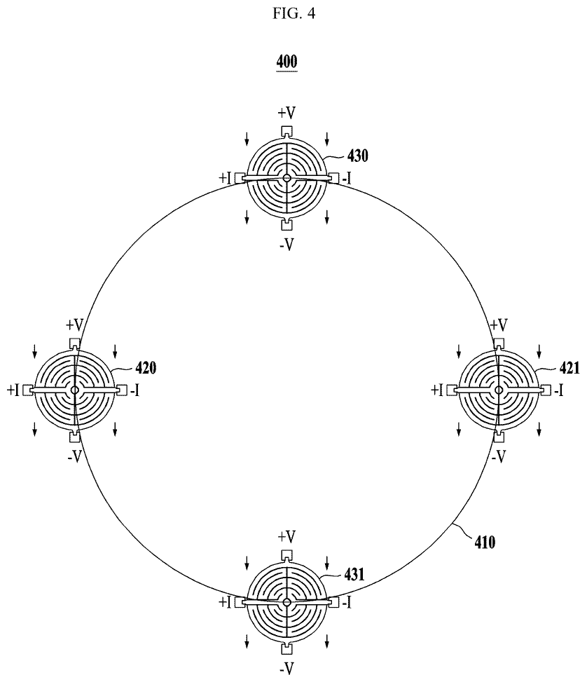

In the case of a magnetic field detection device designed according to a second configuration illustrated in FIG. 4, a magnetic field measurement unit and a magnetic field detection unit are included in a first magnetic sensor, a second magnetic sensor, a third magnetic sensor and a fourth magnetic sensor.

The first magnetic sensor, the second magnetic sensor, the third magnetic sensor and the fourth magnetic sensor may be positioned under the magnetic field conversion unit.

The first magnetic sensor and the second magnetic sensor may detect the X-axis magnetic field and the Z-axis magnetic field, and the third magnetic sensor and the fourth magnetic sensor may detect the Y-axis magnetic field and the Z-axis magnetic field.

In the case of a magnetic field detection device designed according to a third configuration illustrated in FIG. 4, a magnetic sensor for detecting an X-axis magnetic field and a magnetic sensor for detecting a Y-axis magnetic field may be respectively formed on a first wafer substrate and a second wafer substrate which are different wafer substrates.

Accordingly, the present invention can provide a three-axis magnetic field detection device and method for generating a stray field having a magnetic field direction according to an outer magnetic field using a magnetic field conversion unit based on magnetic particles and for detecting the magnetic field direction of the stray field through a magnetic sensor to detect a three-axis magnetic field.

In addition, the present invention may detect the Z-axis magnetic field by the magnetic sensor by using a magnetic particle-based magnetic field converter that generates a stray field, together with the magnetic sensor that measures and detects the X-axis and Y-axis magnetic fields.

FIG. 2 illustrates a first configuration according to the arrangement of a magnetic sensor, which includes a magnetic field measurement unit and a magnetic field detection unit, and a magnetic field conversion unit, in the three-axis magnetic field detection device according to an embodiment of the present invention.

FIG. 2 illustrates a three-axis magnetic field detection device designed according to the first configuration according to an embodiment of the present invention wherein magnetic sensors are arranged under the magnetic field conversion unit and a magnetic sensor for detecting a magnetic field of a different axis is separately disposed.

Referring to FIG. 2, a three-axis magnetic field detection device 200 according to an embodiment of the present invention includes a magnetic field conversion unit 210, a magnetic sensor 220, a magnetic sensor 221, and a magnetic sensor 231.

For example, the magnetic field conversion unit 210 may be referred to as a magnetic field converter, and the magnetic sensor 220, the magnetic sensor 221, and the magnetic sensor 230 include a magnetic field measurement unit and a magnetic field detection unit.

The maximum length including the magnetic sensor 220, the magnetic sensor 221 and the magnetic field conversion unit 210 may be 2 mm, and may occupy a large area compared to the sensors.

The magnetic sensor 220 and magnetic sensor 221 under the magnetic field conversion unit 210, and the magnetic sensor 230 located at the outer side have detection directions on a plane.

The magnetic sensor 220 and the magnetic sensor 221 may measure the magnetic field direction of the X-axis magnetic field, and the magnetic sensor 230 may measure the magnetic field direction of the Y-axis magnetic field.

In addition, the magnetic sensor 220 and the magnetic sensor 221 may detect the X-axis magnetic field, and the magnetic sensor 230 may detect the Y-axis magnetic field.

According to an embodiment of the present invention, output signals of the magnetic sensor 220 and magnetic sensor 221 under the magnetic field conversion unit 210 of the three-axis magnetic field detection device 200 may be determined by the Z-axis magnetic field in the magnetic field on the plane.

The direction of the X-axis magnetic field and the direction of the consequent stray field are the same.

In contrast, the direction of the Z-axis magnetic field and the direction of the stray field are opposite to each other with respect to the magnetic field conversion unit 210.

Accordingly, the output signal of the magnetic sensor may be defined as in Mathematical Expression 3 below:

$$\{ \begin{matrix}{V}_{x} = \frac{1}{2} ( {V}_{sensor 1} + {V}_{sensor 2} ) \\ {V}_{y} = {V}_{sensor 3} \\ {V}_{z} = \frac{1}{2} ( {V}_{sensor 1} - {V}_{sensor 2} )\end{matrix} \qquad [ Mathematical Expression 1 ]$$

In Mathematical Expression 1, Vₓ may represent the output for the X-axis magnetic field, V_{y} may represent the output for the Y-axis magnetic field, Vz may represent the output for the Z-axis magnetic field, Vₛₑₙₛₒᵣ₁ may correspond to the magnetic sensor 220, Vₛₑₙₛₒᵣ₂ may correspond to the magnetic sensor 221, and Vₛₑₙₛₒᵣ₃ may correspond to the magnetic sensor 230.

According to an embodiment of the present invention, the three-axis magnetic field detection device 200 may determine the arrangement and design of the magnetic sensor and the magnetic field conversion unit through simulation results for stray field distribution to detect the z-axis magnetic field.

The intensity of the stray field is strongest at the lower outer edge of the magnetic field conversion unit, so the first configuration may be formed in a structure wherein the magnetic sensor is arranged at the lower outer edge of the magnetic field conversion unit.

The three-axis magnetic field detection device 200 according to an embodiment of the present invention may use a magnetic field converter, manufactured by mixing epoxy with magnetic particles having low magnetic hysteresis effect such as superparamagnetic nanoparticles, instead of a soft magnetic permalloy magnetic field detector to detect a three-axis magnetic field.

Since the three-axis magnetic field detection device 200 according to an embodiment of the present invention is manufactured by a thermal curing process after manufacturing a mold using photolithography, it has the advantage of being able to integrate the sensor and the magnetic converter more accurately, compared to using an adhesive resin to bond a permalloy magnetic field converter.

Accordingly, the present invention may freely determine the positions of the magnetic sensor, which functions as a magnetic field measurement unit and a magnetic field detection unit, and the magnetic field converter, which functions as a magnetic field conversion unit, according to the manufacturer's intention using photolithography or inkjet and heat treatment processes, thereby improving reproducibility.

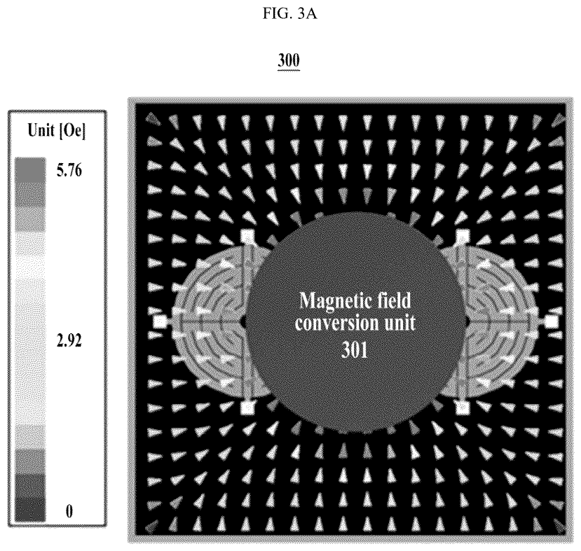

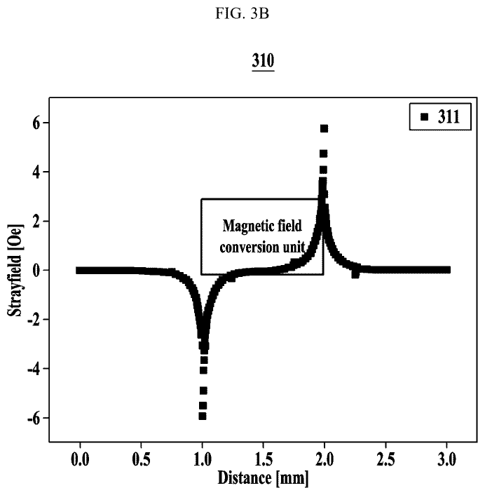

FIGS. 3A and 3B illustrate a stray field generated in the magnetic field conversion unit of the three-axis magnetic field detection device according to an embodiment of the present invention.

FIG. 3A illustrates the distribution of the stray field generated in the magnetic field conversion unit of the three-axis magnetic field detection device according to an embodiment of the present invention.

Referring to FIG. 3A, the distribution of a stray field measured by the three-axis magnetic field detection device according to an embodiment of the present invention may be as shown in a graph 300. For example, the distribution of the stray field may be the intensity distribution of the stray field.

The graph 300 illustrates the stray field intensity distribution by the Z-axis magnetic field.

In the graph 300, magnetic sensors including the magnetic field measurement unit and the magnetic field detection unit are placed under a magnetic field conversion unit 301.

The graph 300 illustrates that a stray field is generated around the magnetic field conversion unit 301.

The graph 300 is related to the arrangement of the magnetic field conversion unit and the magnetic sensors in the three-axis magnetic field detection device according to the first configuration illustrated in FIG. 2.

The graph 300 illustrates that the magnetic sensors located on both sides of the magnetic field conversion unit 301 have different detection directions on the plane.

FIG. 3b illustrates the direction of a stray field generated in the magnetic field conversion unit of the three-axis magnetic field detection device according to an embodiment of the present invention.

Referring to FIG. 3B, the direction of the stray field measured in the three-axis magnetic field detection device according to an embodiment of the present invention may be the same as shown in the graph 300.

A graph 310 illustrates that the direction of the stray field 311 is formed in an opposite direction with respect to the magnetic field conversion unit.

In other words, the graph 310 illustrates a change in the magnetic direction of the stray field by the Z-axis magnetic field.

Based on the graphs 300 and 310, the output signal of the magnetic sensor under the magnetic field conversion unit is determined by the magnetic field on the plane.

It can be confirmed from the graphs 300 and 310 that the directions of the stray fields of the Z-axis magnetic field are opposite to each other with respect to the magnetic field conversion unit.

Meanwhile, the directions of the X-axis and Y-axis magnetic fields and the direction of the consequent stray field may be the same.

The present invention may detect the Z-axis magnetic field by installing the magnetic field conversion unit using magnetic particles, in addition to installing a series of X-axis and Y-axis magnetic sensors, to detect a three-axis magnetic field.

The magnetic particles are superparamagnetic nanoparticles, and since the magnetic hysteresis phenomenon does not occur due to their characteristics, a separate compensation circuit is not required.

In addition, when manufacturing the magnetic field conversion unit, the integrated location of the magnetic conversion unit and the magnetic sensor may be freely determined through a lithography process, an inkjet process, and a thermal curing process.

The direction in which the magnetic field can be detected is different depending on the type of magnetic sensor (e.g., semiconductor Hall sensor, a magnetoresistance sensor). Since the magnetic field conversion unit according to an embodiment of the present invention has a magnetization direction according to the direction of the magnetic field, it may be applied regardless of the type of sensor.

FIG. 4 illustrates a second configuration according to the arrangement of a magnetic sensor, which includes a magnetic field measurement unit and a magnetic field detection unit, and a magnetic field conversion unit in the three-axis magnetic field detection device according to an embodiment of the present invention.

FIG. 4 illustrates a three-axis magnetic field detection device designed according to the second configuration according to a method for reducing the area occupied by the magnetic sensor according to an embodiment of the present invention.

Referring to FIG. 4, a three-axis magnetic field detection device 400 according to an embodiment of the present invention includes a magnetic field conversion unit 410, a magnetic sensor 420, a magnetic sensor 421, a magnetic sensor 430 and a magnetic sensor 431.

The three-axis magnetic field detection device 200 according to an embodiment of the present invention illustrated in FIG. 2 requires a separate external space for a sensor in addition to the magnetic field conversion unit according to the first configuration.

Accordingly, when a wafer with a narrow area is required, the arrangement of magnetic sensors may be considered as in the second configuration.

That is, the second configuration has an improvement in area utilization, compared to the first configuration.

According to the second configuration, the magnetic sensor 420, the magnetic sensor 421, the magnetic sensor 430 and the magnetic sensor 431 detect a stray field generated by the magnetic field conversion unit 410.

The magnetic sensor 420 and the magnetic sensor 421 measure and detect the X-axis magnetic field on the plane, and the magnetic sensor 430 and the magnetic sensor 431 measure and detect the Y-axis magnetic field.

In the case of the direction of exchange magnetic anisotropy for determining a measurement axis, the magnetic sensor 420 and the magnetic sensor 421 corresponding to the X-axis sensor are perpendicular to the magnetic sensor 430 and the magnetic sensor 431 corresponding to the Y-axis sensor.

As in the three-axis magnetic field detection device according to the first configuration, the directions of the magnetic fields on X and Y axes on the plane are the same as the direction of the stray field, and in contrast, the direction of the Z-axis magnetic field is opposite to the direction of the stray field.

Accordingly, an output signal according to the detection of the magnetic field on each axis may be produced as shown in Mathematical Expression 2 below:

$$\{ \begin{matrix}{V}_{x} = \frac{1}{2} ( {V}_{sensor 1} + {V}_{sensor 2} ) \\ {V}_{y} = \frac{1}{2} ( {V}_{sensor 3} + {V}_{sensor 4} ) \\ {V}_{z} = \frac{1}{2} ( {V}_{sensor 1} - {V}_{sensor 2} )\end{matrix} \qquad [ Mathematical Expression 2 ]$$

In Mathematical Expression 2, Vₓ may represent an output for the X-axis magnetic field, V_{y} may represent an output for the Y-axis magnetic field, Vz may represent the output for the Z-axis magnetic field, Vₛₑₙₛₒᵣ₁ may correspond to the magnetic sensor 420, Vₛₑₙₛₒᵣ₂ may correspond to the magnetic sensor 421, Vₛₑₙₛₒᵣ₃ may correspond to the magnetic sensor 430, and Vₛₑₙₛₒᵣ₄ may correspond to the magnetic sensor 431.

Meanwhile, a three-axis magnetic field detection device 400 may detect the Z-axis magnetic field through the magnetic sensor 430 and magnetic sensor 431 that detect the Y-axis. As the magnetic field direction of the Z-axis magnetic field is opposite to the magnetic field direction of the stray field generated by the Y-axis magnetic field, the Z-axis magnetic field may be measured by performing an operation that divides a value excluding a magnetic field direction measured through the magnetic sensor 431 by half for a magnetic field direction measured through the magnetic sensor 430.

For example, the three-axis magnetic field detection device 400 may detect the Z-axis magnetic field with an output for the Z-axis magnetic field at a value half a difference between the output of the magnetic sensor 430 and the output of the magnetic sensor 431.

In other words, the three-axis magnetic field detection device 400 may detect the Y-axis magnetic field and the Z-axis magnetic field through the magnetic sensor 430 and the magnetic sensor 431.

In addition, the three-axis magnetic field detection device 400 may detect the X-axis magnetic field and the Z-axis magnetic field through the magnetic sensor 420 and the magnetic sensor 421.

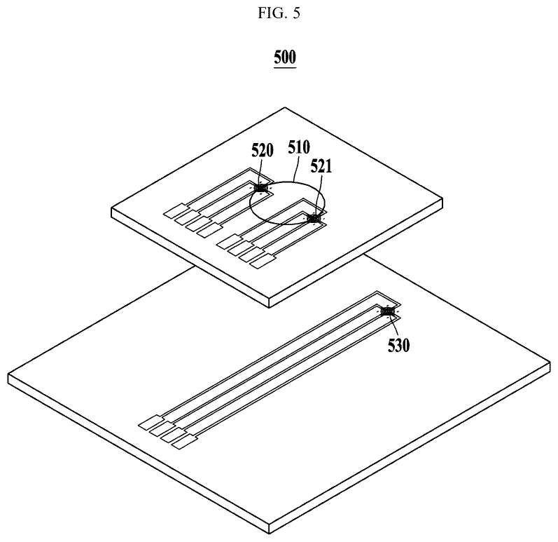

FIG. 5 illustrates a third configuration according to the arrangement of a magnetic sensor, which includes a magnetic field measurement unit and a magnetic field detection unit, and a magnetic field conversion unit in the three-axis magnetic field detection device according to an embodiment of the present invention.

FIG. 5 illustrates a three-axis magnetic field detection device designed according to the third configuration according to an embodiment of the present invention in which a magnetic field annealing process is required.

Referring to FIG. 5, a three-axis magnetic field detection device 500 according to an embodiment of the present invention includes a magnetic field conversion unit 510, a magnetic sensor 520, a magnetic sensor 521 and a magnetic sensor 530.

Each of the magnetic sensor 520, the magnetic sensor 521 and the magnetic sensor 530 includes a magnetic field measurement unit and a magnetic field detection unit, and the magnetic field conversion unit 510 may be referred to as a magnetic field converter.

The measurement directions of the magnetic sensor 520, the magnetic sensor 521 and the magnetic sensor 530 are determined by the direction of a reference axis, as in the exchange magnetic anisotropy.

When a magnetic field is applied to the magnetic sensor 520, the magnetic sensor 521, and the magnetic sensor 530 during a sputtering process of manufacturing the magnetic sensor 520, the magnetic sensor 521, and the magnetic sensor 530, the direction of the exchange magnetic anisotropy may be determined, so that magnetic sensors for measuring the X-axis and Y-axis magnetic fields may be manufactured on one wafer.

However, when manufactured through a magnetic field-annealing method including a heat treatment process, only a magnetic sensor for a specific axis may be manufactured because the exchange magnetic anisotropy is lost when a specific temperature is reached during the process.

Accordingly, to manufacture sensors capable of detecting magnetic fields of different axes on the plane, the three-axis magnetic field detection device 500 according to the third configuration may be manufactured in a manner of manufacturing each sensor on a separate wafer and then combining them.

For example, the magnetic sensor 520 and the magnetic sensor 521 are positioned adjacent to the magnetic field conversion unit 510 and formed on the same wafer substrate.

On the other hand, the third magnetic sensor 530 is formed on a wafer substrate different from those of the magnetic sensor 520, the magnetic sensor 521 and the magnetic field conversion unit 510, and then coupled.

The three-axis magnetic field detection device 500 may detect the magnetic field of the X axis, which is an axis on the plane, and the Z-axis magnetic field, which is converted by the magnetic field conversion unit 510, using the magnetic sensor 520 and magnetic sensor 521, positioned at the upper wafer, and the magnetic field conversion unit 510.

The three-axis magnetic field detection device 500 may detect the Y-axis magnetic field, which corresponds to another axis on the plane, through the magnetic sensor 530 positioned at the lower wafer.

Accordingly, the magnetic sensor 520 and the magnetic sensor 521 may detect the X-axis magnetic field and the Z-axis magnetic field, and the magnetic sensor 530 may detect the Y-axis magnetic field.

That is, the present invention can provide the three-axis magnetic field detection device 500 capable of detecting a three-axis magnetic field, in preparation for a manufacturing environment requiring a magnetic field annealing process.

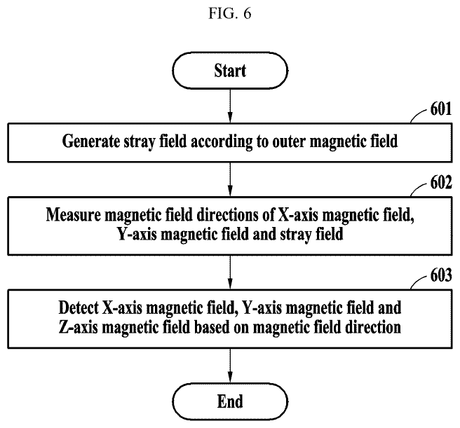

FIG. 6 illustrates a three-axis magnetic field detection method according to an embodiment of the present invention.

FIG. 6 illustrates a procedure of the three-axis magnetic field detection method performed by the three-axis magnetic field detection device according to an embodiment of the present invention.

For example, the three-axis magnetic field detection device may include a magnetic sensor including a magnetic field measurement unit and a magnetic field detection unit; and a magnetic field conversion unit, and the magnetic field conversion unit may be referred to as a magnetic field converter.

Referring to FIG. 6, a three-axis magnetic field detection method according to an embodiment of the present invention includes a step 601 of generating a stray field according to an outer magnetic field.

That is, according to the three-axis magnetic field detection method according to an embodiment of the present invention, the magnetic field converter may generate a stray field having a magnetic field direction according to the magnetic field direction of an outer magnetic field using magnetic particles.

In a step 602, the three-axis magnetic field detection method according to an embodiment of the present invention includes measuring the magnetic field directions of the X-axis magnetic field, the Y-axis magnetic field and the stray field.

That is, according to the three-axis magnetic field detection method according to an embodiment of the present invention, the magnetic sensor may measure the magnetic field directions for the X-axis magnetic field, the Y-axis magnetic field and the stray field in relation to an outer magnetic field.

In the step 603, the three-axis magnetic field detection method according to an embodiment of the present invention detects the X-axis magnetic field, the Y-axis magnetic field and the Z-axis magnetic field based on the magnetic field directions.

That is, according to the three-axis magnetic field detection method according to an embodiment of the present invention, the magnetic sensor detects the X-axis magnetic field, the Y-axis magnetic field and the Z-axis magnetic field based on the previously measured magnetic field directions.

For example, according to the three-axis magnetic field detection method, the X-axis magnetic field may be detected when the magnetic field direction of the stray field is the same as the magnetic field direction of the X-axis magnetic field, and the Z-axis magnetic field may be detected when the magnetic field direction of the stray field differs from the magnetic field direction of the X-axis magnetic field.

In addition, according to the three-axis magnetic field detection method, the Y-axis magnetic field may be detected when the magnetic field direction of the stray field is the same as the magnetic field direction of the Y-axis magnetic field, and the Z-axis magnetic field may be detected when the magnetic field direction of the stray field differs from the magnetic field direction of the Y-axis magnetic field.

Accordingly, the present invention can provide a three-axis magnetic field detection device and method that can be applied regardless of the type of sensor to detect a three-axis magnetic field as a magnetic particle-based magnetic field conversion unit included in the three-axis magnetic field detection device generates a stray field having a magnetization direction according to the direction of magnetic field.

In addition, the present invention can determine the positions of a magnetic sensor and a magnetic field converter in consideration of the characteristic that the output signal of a magnetic field detection unit is determined by the intensity of a stray field converted by the magnetic field conversion unit, thereby being capable of improving a magnetic field detection rate.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. A three-axis magnetic field detection device, comprising:
a magnetic field conversion unit for generating a stray field having a magnetic field direction according to a magnetic field direction of an outer magnetic field using magnetic particles;
a magnetic field measurement unit for measuring magnetic field directions for an X-axis magnetic field, a Y-axis magnetic field and the stray field in relation to the outer magnetic field; and
a magnetic field detection unit for detecting the X-axis magnetic field, the Y-axis magnetic field and the Z-axis magnetic field based on the measured magnetic field direction.

2. The three-axis magnetic field detection device according to claim 1, wherein
the magnetic field detection unit detects the X-axis magnetic field when the magnetic field direction of the stray field is identical to the magnetic field direction of the X-axis magnetic field, and detects the Z-axis magnetic field when the magnetic field direction of the stray field differs from the magnetic field direction of the X-axis magnetic field.

3. The three-axis magnetic field detection device according to claim 1, wherein the magnetic field detection unit detects the Y-axis magnetic field when the magnetic field direction of the stray field is identical to the magnetic field direction of the Y-axis magnetic field, and detects the Z-axis magnetic field when the magnetic field direction of the stray field differs from the magnetic field direction of the Y-axis magnetic field.

4. The three-axis magnetic field detection device according to claim 1, wherein, when the outer magnetic field is either an X-axis magnetic field or a Y-axis magnetic field, the magnetic field conversion unit generates a stray field having a magnetic field direction identical to that of either the X-axis magnetic field or the Y-axis magnetic field, and, when the outer magnetic field is a Z-axis magnetic field, the magnetic field conversion unit generates a stray field having a magnetic field direction opposite to that of the Z-axis magnetic field.

5. The three-axis magnetic field detection device according to claim 4, wherein the magnetic field measurement unit and the magnetic field detection unit are comprised in each of a first magnetic sensor, a second magnetic sensor and a third magnetic sensor,
the first magnetic sensor and the second magnetic sensor are positioned under the magnetic field conversion unit,
the third magnetic sensor is positioned separately from the magnetic field conversion unit,
the first magnetic sensor and the second magnetic sensor detect the X-axis magnetic field and the Z-axis magnetic field, and
the third magnetic sensor detects the Y-axis magnetic field.

6. The three-axis magnetic field detection device according to claim 5, wherein the magnetic field detection unit detects the X-axis magnetic field by combining an output signal of the first magnetic sensor with an output signal of the second magnetic sensor and by dividing the output signal by the number of magnetic sensors that output the output signal, detects the Z-axis magnetic field by excluding an output signal of the second magnetic sensor from the output signal of the first magnetic sensor and by dividing the output signal by the number of the magnetic sensors, and detects an output signal of the third magnetic sensor as the Y-axis magnetic field.

7. The three-axis magnetic field detection device according to claim 5, wherein the first magnetic sensor, the second magnetic sensor, the magnetic field conversion unit and the third magnetic sensor are positioned on a first wafer substrate.

8. The three-axis magnetic field detection device according to claim 5, wherein the first magnetic sensor, the second magnetic sensor and the magnetic field conversion unit are positioned on the first wafer substrate, and
the third magnetic sensor is positioned on a second wafer substrate different from the first wafer substrate.

9. The three-axis magnetic field detection device according to claim 4, wherein the magnetic field measurement unit and the magnetic field detection unit are comprised in each of the first magnetic sensor, the second magnetic sensor, the third magnetic sensor and the fourth magnetic sensor,
the first magnetic sensor, the second magnetic sensor, the third magnetic sensor and the fourth magnetic sensor are positioned under the magnetic field conversion unit,
the first magnetic sensor and the second magnetic sensor detect the X-axis magnetic field and the Z-axis magnetic field, and
the third magnetic sensor and the fourth magnetic sensor detect the Y-axis magnetic field and the Z-axis magnetic field.

10. The three-axis magnetic field detection device according to claim 9, wherein the magnetic field detection unit detects the X-axis magnetic field by combining an output signal of the first magnetic sensor with an output signal of the second magnetic sensor and by dividing the output signal by the number of magnetic sensors that output the output signal, detects the Z-axis magnetic field by excluding an output signal of the second magnetic sensor from the output signal of the first magnetic sensor and by dividing the output signal by the number of the magnetic sensors, detects the Y-axis magnetic field by combining an output signal of the third magnetic sensor with an output signal of the fourth magnetic sensor and by dividing the output signal by the number of the magnetic sensors, and detects the Z-axis magnetic field by excluding an output signal of the fourth magnetic sensor from the output signal of the third magnetic sensor and dividing the output signal by the number of the magnetic sensors.

11. A three-axis magnetic field detection method, comprising:
generating, by a magnetic field conversion unit, a stray field having a magnetic field direction according to a magnetic field direction of an outer magnetic field using magnetic particles;
measuring, by a magnetic field measurement unit, magnetic field directions for an X-axis magnetic field, a Y-axis magnetic field and the stray field in relation to the outer magnetic field; and
detecting, by a magnetic field detection unit, the X-axis magnetic field, the Y-axis magnetic field and the Z-axis magnetic field based on the measured magnetic field direction.

12. The three-axis magnetic field detection method according to claim 11, wherein the detecting comprises:
detecting the X-axis magnetic field when the magnetic field direction of the stray field is identical to the magnetic field direction of the X-axis magnetic field; and
detecting the Z-axis magnetic field when the magnetic field direction of the stray field differs from the magnetic field direction of the X-axis magnetic field.

13. The three-axis magnetic field detection method according to claim 11, wherein the detecting comprises:
detecting the Y-axis magnetic field when the magnetic field direction of the stray field is identical to the magnetic field direction of the Y-axis magnetic field; and
detecting the Z-axis magnetic field when the magnetic field direction of the stray field differs from the magnetic field direction of the Y-axis magnetic field.
